(19) United States
(12) Patent Application Publication
(10) Pub. No.: US 2005/0006599 A1
(43) Pub. Date: Jan. 13, 2005

(54) Production of nanocrystal beams

(76) Inventor: Derek Eastham, Warrington (GB)

Correspondence Address: Akin Gump Strauss Hauer & Feld, Suite 1900, 711 Louisiana, Houston, TX, 77002, US

(21) Appl. No.: 10/476,520

(22) PCT Filed: Apr. 22, 2002
(86) PCT No.: PCT/GB02/01836

(30) Foreign Application Priority Data
Apr. 30, 2001 (GB) 0110523.8

(51) Int. Cl. H01J 27/00; G21K 5/10; H01J 37/08

(52) U.S. Cl. 250/492.21; 250/424; 250/398

(57) ABSTRACT

Apparatus for producing a beam of clustered atoms comprises a nozzle (17) ejecting atomic clusters from a source (10, 11) in a gas stream. The nozzle (17) comprises a passage having an inwardly tapered inlet portion (17a) and an outwardly tapered outlet portion (17c) whereby turbulence in the region of the inlet and outlet of the nozzle is minimised.

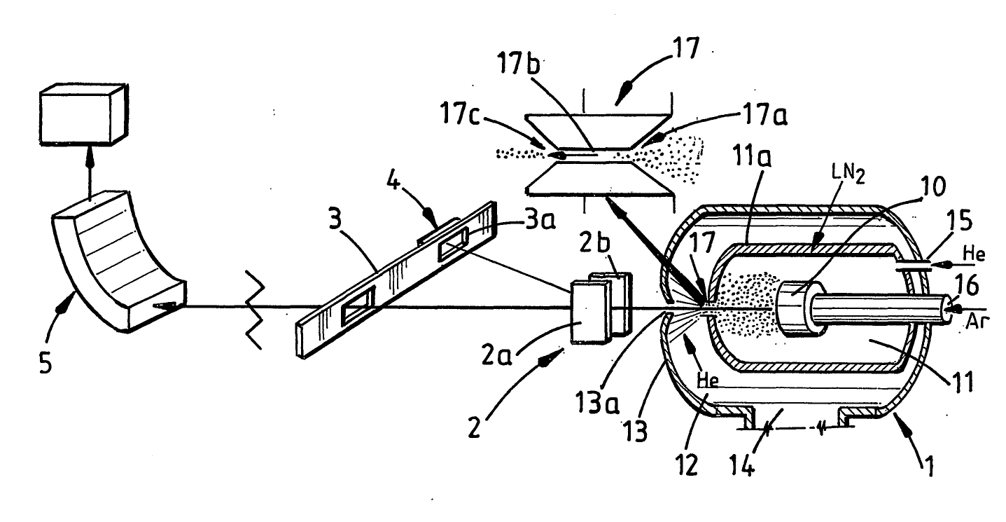

The present invention relates to an apparatus and method for producing a beam of nanocrystals. In particular, the invention relates to the production of an intense, parallel beam of nanocrystals, which can be easily mass selected and “soft” landed on a substrate, from an atomic cluster source such as a magnetron.

The term “nanocrystal” is well known and refers to nano-scale clusters of atoms. The study of deposited nanocrystals (typically of a diameter less than 10 nm) is an expanding field motivated by the realisation that novel materials and nano structures can be made using deposited nanocrystals as the primary building blocks. For instance, a two dimensional superlattice of nanocrystals may be created by locating nanocrystals on a patterned substrate. There are many interesting potential applications for such structures, including manufacture of high-density magnetic storage media and production of quantum crystal lasers. Such applications require a mono-dispersed assembly of nanocrystals. For example, the inhomogeneous broadening of a nanocrystal laser, which is primarily caused by the quantum confinements of electrons, can be directly related to the size spread of the semiconductor nanocrystals. There is therefore a need to develop a technique whereby a substantial portion of the output of a cluster source can be separated and concentrated into a narrow parallel beam of substantially fixed energy.

One conventional method of producing a beam of nanocrystals is to use a magnetron gas-aggregation source as mentioned above. In such a source a conventional magnetron is used to sputter material into an inert atmosphere of argon and helium in a vacuum chamber (typically at a pressure in a range from 0.1 mbar to 3 mbar) which is cooled (typically to a temperature of around −185° C.) by means of an enclosing jacket containing liquid nitrogen. Atoms of a target material present in the magnetron are sputtered into this gas mixture where they aggregate and form nanocrystals typically in a size range from 1.5 nm to 10 nm. The nanocrystals are ejected from the chamber through an aperture into an expansion chamber (held at reduced pressure) in which the helium/argon gas rapidly expands and is skimmed off by a skimmer leaving a beam of nanocrystals which is transported into a high vacuum chamber in which deposition occurs.

The nanocrystals produced by such a conventional source will have a wide spread of masses and thus for most practical applications mass selection must be performed prior to deposition. Conventionally this involves first ionising the nanocrystals for subsequent separation using appropriate electrostatic optics. Because of the wide spread in nanocrystal velocities produced by such conventional systems, relatively sophisticated optics, such as a quadrapole arrangement, are required. In addition, a conventional RF quadrapole creates relatively large angular spreads in the beam which reduces brightness.

The wide spread in velocities also means that there will be relatively few nanocrystals at any particular energy/mass combination. As a result, in a conventional system a relative large mass spread in the selected nanocrystals must be tolerated in order to attain a practically useful beam intensity. This problem is exacerbated by the fact that conventional ionisation procedures are relatively inefficient in that only something in the region of 2% of the nanocrystals produced by the source are ionised.

It is an object of the present invention to provide an apparatus and method for producing a beam of nanocrystals which obviates or mitigates the above disadvantages.

According to a first aspect of the present invention there is provided apparatus for producing a beam of clustered atoms, the apparatus comprising:
a source of atomic clusters;
a nozzle for ejecting said atomic clusters from said source in a gas stream;
wherein the nozzle comprises a passage having an inwardly tapered inlet portion and an outwardly tapered outlet portion whereby turbulence in the region of the inlet and outlet of the nozzle is minimised.

According to a second aspect of the present invention there is provided apparatus for depositing clustered atoms on a substrate surface, the apparatus comprising apparatus for producing a beam of clustered atoms as defined above and further comprising means for producing a retarding voltage in the region of said substrate to reduce the energy of the nanocrystal beam and “soft” land the nanocrystals on said substrate surface.

According to a third aspect of the present invention there is provided apparatus for producing a beam of nanocrystals having an angular divergence of less than 10° from a gas stream entraining said nanocrystals, the apparatus comprising a nozzle having a inwardly tapered inlet portion for receiving said stream, a central substantially constant diameter portion for inducing laminar gas flow in said stream, and an outwardly tapered outlet portion for ejecting said beam of nanocrystals.

According to a fourth aspect of the present invention there is provided a method of producing a beam of mass-selected nanocrystals produced by a magnetron cluster source, the method comprising:
ejecting the nanocrystals in a gas stream using a nozzle comprising an inwardly tapered inlet portion, a substantially constant diameter central portion, and an outwardly tapered outlet portion;
directing the beam ejected from said nozzle to an electrostatic mass selector and steerer assembly without any additional ionisation or acceleration of the beam; and
selecting nanocrystals of a desired mass or mass range by appropriate control of said electrostatic mass selector and steerer.

A specific embodiment of the present invention will now be described, by way of example only, with reference to the accompanying drawing which is a schematic illustration of apparatus for depositing size-selected nanocrystals on a substrate surface.

Referring to the drawing, in overview the apparatus comprises a means for producing nanocrystals 1, a mass selector and steerer 2, an aperture plate 3 supporting a sample substrate 4, and a “time of flight” measurement system and electrostatic analyser 5. Other elements of the apparatus which are not illustrated will be described further below.

The means for producing nanocrystals 1 comprises a magnetron 10 housed within a chamber 11 which is defined, and maintained at low temperature (about −185° C.) by a liquid nitrogen cooled jacket 11a which is itself housed within a second, larger, expansion chamber 12. The chamber 12 supports at one end a skimmer 13 with a funnelled opening 13a and is connected to a vacuum pump (not shown) via port 14. With the exception of the opening 13a, the chamber 12 is sealed so that a reduced pressure may be maintained within the chambers 12 and 11 by operation of the vacuum pump.

Within the magnetron 10 is a cathode plate bearing target material (not shown) surrounded by suitably located anodes (not shown). An electric field is established between the cathode plate and the anodes, and a magnet (not shown) is positioned behind the cathode plate to produce a magnetic field in front of the plate.

Helium is supplied to the chamber 11 via inlet 15 and is maintained at a pressure of the order of 1.3-1.5 mbar by the vacuum pump. Low pressure argon gas is introduced into the magnetron 10 in a continuous stream 16 and is ionised by the electric field established between the target bearing cathode plate and the anodes. Electrons which are separated from the argon atoms strike the target thereby liberating atoms of the target material.

Within the cooled chamber 11 the target atoms have a limited mobility due to the presence of the gaseous helium atoms and thus tend to drift and stick together by a process of gas aggregation thereby forming various sized clusters or nanocrystals. These nanocrystals pass from the cooled chamber 11 into the chamber 12 in a stream of helium and argon. Within the chamber 12 the helium argon gas mixture rapidly expands and is skimmed off by the skimmer 13 leaving the target nanocrystals to be ejected through the skimmer aperture 13a into a high vacuum chamber containing the mass selector and substrate etc.

In accordance with the present invention, the nanocrystals leave the source via a nozzle 17 provided in the jacket 11. Specifically, the nozzle is a laminar flow expansion nozzle comprising an inwardly tapering inlet portion 17a, a central constant diameter passage 17b, and an outwardly tapering outlet portion 17c. the central passage may typically have a diameter in the region of 3 mm to 5 mm and a length of the order of 10 mm or so. In this particular nozzle design the nanocrystals are carried in the gas mixture which is accelerated through the nozzle with minimal turbulence at both the inlet and outlet of the nozzle. At the outlet 17c the helium/argon gas mixture expands through a large angle ensuring that most of the gas is subsequently removed by the slimmer 13 which has no effect on the beam intensity.

The result is a beam of nanocrystals with a very narrow angular spread dependant only on the nozzle geometry (for instance less than about 6°) and of substantially uniform velocity largely independent of mass (for given conditions in the magnetron source, such as pressure). For instance, a variation in nanocrystal velocity significantly less than m^{1/2} (and even as low as of the order of m^{1/14}) is readily achievable giving a velocity spread Δv/v (at full-width-half-maximum) of less than 2% over the entire nanocrystal mass range. The energy of any particular nanocrystal ejected from the nozzle is therefore almost directly proportional to its mass/size allowing the use of the simple electrostatic analyser 5 and selector/deflector 2 to select and separate nanoparticles of a desired mass/size. The intensity as a function of energy can therefore be directly transformed into a mass distribution for the source output.

In addition, measurements performed by the present inventor have established that in the region of 30% to 40% of the nanocrystals leaving a typical magnetron source have a negative charge (and depending upon the source conditions a similar fraction of positively charged nanocrystals are observed). This fraction is at least an order of magnitude greater than may be expected from the electron beam ionisation process conventionally used to ionise the nanocrystals. Thus with the present invention the beam of nanocrystals leaving the source is sent directly to the electrostatic optics without first being ionised.

All of the above features combine to produce a substantially parallel high intensity monochromatic energy nanocrystal beam. A mass spread (Δm/m-full-width-half-maximum) of less than 5% is readily obtainable, compared with approximately 50% with conventional systems. Higher beam intensities can be achieved by tolerating higher mass spreads, a mass spread of the order of 15% equating to a nanocrystal size spread of the order of 5%. For instance, the present invention has been used to deposit nanocrystals of gold on a graphite substrate achieving an intensity of 5 nanoamps with beam diversion of 6° and size distribution of less than 5%.

The time of flight measurement system and electrostatic energy analyser 5 is a conventional system for determining the velocity and mass verses energy distribution of the nanocrystals and thus further details of operation of this system will not be described here. Periodic measurements made by this system are used to control operation of the mass selector and steerer 2 which in this example is a simple electrostatic stearer comprising two electrostatic plates 2a and 2b. When a voltage is applied across the plates 2a, 2b negatively charged nanocrystals will be deflected through an angle depending upon their mass and energy. The voltage across the plates can be carefully controlled (as a result of the measurements periodically made at the measurement system 5 by pulsing off the voltage applied across the electrostatic plates) to steer nanocrystals of a selected mass towards the sample substrate 4 positioned behind an aperture 3a in the aperture plate 3. Because the nanocrystal beam is substantially parallel and mono-energetic the nanocrystals can be “soft-landed” on the surface of the substrate 4 simply by applying a retarding voltage to the substrate which protects both the nanocrystals and sample surface from damage. The low angular diversions of the beam is also important in that it allows deposition of the nanocrystals at minimum energy without compromising beam intensity.

Although a magnetron is the preferred source of nanocrystals for use with the present invention, because of the inherent ionisation of nanocrystals which occurs in the magnetron plasma, alternative forms of nanocrystal source could be used. The invention relates to the manner in which the nanocrystals are concentrated into a beam which is not dependent on any particular form of source. For instance, the invention can readily be used with a source producing neutral nanocrystals by providing addition, conventional, ionisation equipment to charge the nanocrystals.

It will be appreciated that various other modifications can be made to the apparatus and method described above. For instance, although a simple electrostatic mass selector is preferred, an alternative form of mass selector may be used, such as a quadrapole. If a quadrapole is used it may for instance be situated between the skimmer 13 and the steerer 2 which in such an arrangement will be required only to steer the clusters and will not perform any mass selection. Accordingly, it may be possible to dispense with the time of flight measurement system 5, although it would be preferable to maintain this system to monitor the nanocrystal production and to calibrate the quadrapole. Details of a quadrapole are well known in the art (for instance as used in mass spectrometers) and will not be described here. Similarly, other forms of mass or energy selector which could be used will be evident to the skilled person.

1. Apparatus for producing a beam of clustered atoms, the apparatus comprising:
a source of atomic clusters;
a nozzle for ejecting a nanocrystal beam of said atomic clusters from said source in a gas stream; wherein the nozzle comprises
a passage having an inwardly tapered inlet portion and
an outwardly tapered outlet portion whereby turbulence in the region of the inlet and outlet of the nozzle is minimised.

2. Apparatus according to claim 1, wherein the nozzle comprises
a substantially central constant diameter central portion communicating between said tapered inlet and outlet portions inducing a laminar gas flow.

3. Apparatus according to claim 2, wherein said central portion has a length of the order of 3 to 15 mm and a diameter of the order of 1 to 5 mm.

4. Apparatus according to claim 3, wherein said central portion of the nozzle has a length of the order of 5 to 10 mm and a diameter of the order of 3 mm.

5. Apparatus according to claim 1, wherein the source is located in a first chamber supplied with a stream of inert gas, the first chamber being separated from a second chamber by a wall, the second chamber being maintained at a lower pressure than the first chamber, and said nozzle being provided in an aperture in said wall.

6. Apparatus according to claim 5, wherein the first chamber is maintained at a pressure in the region of about 0.1 mbar to 3 mbar.

7. Apparatus according to claim 5, wherein said second chamber is maintained at a pressure of about 10⁻³ mbar.

8. Apparatus according to claim 5, wherein the second chamber is provided with a skimmer separating the second chamber from a high vacuum chamber, the skimmer having a funnelled opening allow the passage of said nanocrystal beam therethrough whilst skimming said inert gas.

9. Apparatus according to claim 1, wherein the cluster source is a magnetron source.

10. Apparatus according to claim 1, further comprising
an electrostatic mass selector and steerer located downstream of said nozzle for producing a beam of mass selected clusters from the beam ejected from said nozzle.

11. Apparatus according to claim 10, wherein said electrostatic mass selector and steerer comprises
a pair of electrostatic plates and
means for controlling the voltage across said plates to select clusters of a desired mass.

12. Apparatus for depositing clustered atoms on a substrate surface, the apparatus comprising
apparatus for producing a beam of clustered atoms comprising:
a source of atomic clusters,
a nozzle for ejecting a nanocrystal beam of said atomic clusters from said source in a gas stream; wherein the nozzle comprises
a passage having an inwardly tapered inlet portion and
an outwardly tapered outlet portion whereby turbulence in the region of the inlet and outlet of the nozzle is minimised
means for producing a retarding voltage in the region of said substrate to reduce the energy of the nanocrystal beam and “soft” land the atomic clusters on said substrate surface.

13. Apparatus for producing a beam of nanocrystals having an angular divergence of less than 10 from a gas stream entraining said nanocrystals, the apparatus comprising
a nozzle having a inwardly tapered inlet portion for receiving said stream,
a central substantially constant diameter portion for inducing laminar gas flow in said stream, and
an outwardly tapered outlet portion for ejecting said beam of nanocrystals.

14. A method of producing a beam of mass-selected nanocrystals produced by a magnetron cluster source, the method comprising:
ejecting the nanocrystals in a gas stream using a nozzle comprising
an inwardly tapered inlet portion,
a substantially constant diameter central portion, and
an outwardly tapered outlet portion;
directing the beam ejected from said nozzle to an electrostatic mass selector and steerer assembly without any additional ionisation or acceleration of the beam; and
selecting nanocrystals of a desired mass or mass range by appropriate control of said electrostatic mass selector and steerer.

15. (Cancelled.)

16. (Cancelled.)
